(19) United States
(12) Patent Application Publication
(10) Pub. No.: US 2026/0305401 A1
(43) Pub. Date: Oct. 1, 2026

(54) CIRCUIT BOARD AND SEMICONDUCTOR PACKAGE SUBSTRATE COMPRISING SAME

(71) Applicant: LG INNOTEK CO., LTD., Seoul (KR)

(72) Inventors: Yong Ho SON, Seoul (KR); Yong Suk KIM, Seoul (KR); Moo Seong KIM, Seoul (KR)

(73) Assignee: LG INNOTEK CO., LTD., Seoul (KR)

(21) Appl. No.: 19/478,410

(22) PCT Filed: Apr. 29, 2024
(86) PCT No.: PCT/KR2024/005759

§ 371 Date: Oct. 24, 2025

(30) Foreign Application Priority Data
Apr. 27, 2023 (KR) 10-2023-0055823

(51) Int. Cl. H10W 70/60; H10B 80/00; H10D 80/30; H10W 70/05; H10W 70/63; H10W 70/685; H10W 90/00; H10W 90/10

(52) U.S. Cl. CPC H10W 70/618; H10W 70/095; H10W 70/63; H10W 70/685; H10B 80/00; H10D 80/30; H10W 90/10; H10W 90/724

(57) ABSTRACT

A circuit board according to an embodiment includes a first insulating layer having a cavity; a connection member disposed in the cavity of the first insulating layer; and a second insulating layer disposed on the first insulating layer and embedding the connection member, wherein a lower surface of the connection member has a step, and the second insulating layer is in contact with at least a portion of the step of the connection member.

### TECHNICAL FIELD

An embodiment relates to a circuit board and a semiconductor package substrate comprising the same.

### BACKGROUND ART

As performances of electric/electronic products progresses, technologies for disposing a greater number of semiconductor devices on a semiconductor package substrate of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

In addition, semiconductor packages applied to products that provide the Internet of Things (IoT), autonomous vehicles, and high-performance servers are expanding a concept to semiconductor chiplets as the number of semiconductor devices and/or the size of each semiconductor device increases in line with the trend toward high integration, or as the functional parts of semiconductor devices are divided.

Accordingly, an intercommunication between semiconductor devices and/or semiconductor chiplets is becoming important, and accordingly, there is a trend to dispose an interposer between the circuit board of the semiconductor package and the semiconductor devices.

An interposer can function as a redistribution layer that gradually increases a width or depth of a circuit pattern from the semiconductor device to the semiconductor package in order to facilitate the intercommunication between the semiconductor devices and/or semiconductor chiplets, or to interconnect the semiconductor devices and the semiconductor package circuit board, thereby smoothly transmitting electrical signals between the semiconductor device and the semiconductor package circuit board having a relatively large circuit pattern compared to the circuit pattern of the semiconductor device.

Meanwhile, a package substrate and/or interposer applied to a semiconductor package may be equipped with a connection member connected to a semiconductor device and/or a semiconductor chiplet. The connection member functions to horizontally connect a plurality of semiconductor devices and/or semiconductor chiplets. Accordingly, the connection member may be embedded in the package substrate and/or the interposer.

In this case, when a connection member is embedded in a package substrate and/or interposer used in a semiconductor package, the connection member may lift due to reduced adhesive strength, which may deteriorate physical and/or electrical reliability of the connection member.

Furthermore, if the connection member lifts, a flatness of the connection member may deteriorate. This deterioration in the flatness of the connection member may result in height variations between a plurality of electrode parts provided on the connection member, which may prevent the semiconductor device from being stably disposed on the package substrate and/or interposer used in the semiconductor package.

For example, the connection member may have a plurality of pads on an upper surface, and the package substrate and/or interposer applied to the semiconductor package may include a plurality of electrodes connected to a plurality of pads of the connection member. The plurality of electrodes are connected to terminals provided in the semiconductor device. If the flatness of the connection member deteriorates, heights of the plurality of pads provided on the upper surface of the connection member may differ, and thus heights of the plurality of electrodes provided on the plurality of pads may differ. At this time, if the heights of the plurality of electrodes are different from each other, there may be a problem in that a semiconductor device and/or a semiconductor chiplet may not be stably mounted on a plurality of electrodes. As a result, there may be a problem in that operating characteristics, reliability, and yield of the semiconductor device and/or semiconductor chiplets are deteriorated.

### DISCLOSURE

### Technical Problem

The embodiment provides a circuit board having a novel structure and a semiconductor package substrate including the same.

In addition, the embodiment provides a circuit board capable of improving the adhesion between the circuit board and a connection member, and a semiconductor package substrate including the same.

In addition, the embodiment provides a circuit board capable of improving the flatness of the connection member, and a semiconductor package substrate including the same.

In addition, the embodiment provides a circuit board capable of ensuring that a plurality of pads of a connection member have uniform heights, and a semiconductor package substrate including the same.

In addition, the embodiment provides a circuit board capable of ensuring that a plurality of electrodes disposed on a connection member have uniform heights, and a semiconductor package substrate including the same.

In addition, the embodiment provides a circuit board with improved heat dissipation characteristics, and a semiconductor package substrate including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a first insulating layer having a cavity; a connection member disposed in the cavity of the first insulating layer; and a second insulating layer disposed on the first insulating layer and embedding the connection member, wherein a lower surface of the connection member has a step, and wherein the second insulating layer is in contact with at least a portion of the step of the connection member.

In addition, the connection member includes an insulating part, and a lower surface of the insulating part has a step.

In addition, the connection member further includes a metal layer disposed on the lower surface of the insulating part, and a lower surface of the metal layer has a step corresponding to the step of the insulating part.

In addition, the insulating part includes an inner insulating part and a lower insulating part disposed on a lower surface of the inner insulating part, and the metal layer is disposed on a lower surface of the lower insulating part.

In addition, the lower surface of the lower insulating part and the lower surface of the metal layer each have a step.

In addition, a width of the inner insulating part in a horizontal direction is smaller than a width of the lower insulating part in the horizontal direction, and the metal layer is provided with a step on the lower surface of the inner insulating part, a side surface of the lower insulating part, and the lower surface of the lower insulating part.

In addition, the circuit board further comprises an electrode part embedded in the insulating layer, wherein the electrode part includes an electrode pattern disposed on a bottom surface of the cavity and overlapping the connection member in a vertical direction, and a width of the electrode pattern in the horizontal direction is greater than a width of the metal layer in the horizontal direction.

In addition, the width of the metal layer in the horizontal direction is the same as a width of the insulating part of the connection member in the horizontal direction.

In addition, the circuit board further comprises an adhesive member disposed between the electrode pattern and the metal layer of the connection member, wherein an upper surface of the adhesive member is in contact with the metal layer, and a lower surface of the adhesive member is in contact with the electrode pattern.

In addition, a width of the adhesive member in the horizontal direction is smaller than a width of the electrode pattern in the horizontal direction.

In addition, a width of the adhesive member in the horizontal direction is greater than a width of the metal layer of the connection member in the horizontal direction.

In addition, the adhesive member includes a first portion that contacts an upper surface of the electrode pattern and a lower surface of the metal layer, and a second portion that extends upward from the first portion and contacts a side surface of the metal layer.

In addition, the adhesive member includes an overlapping region overlapping the connection member in the vertical direction, and the overlapping region includes a contact portion that contacts the connection member and a non-contact portion that does not contact the connection member.

In addition, the circuit board further includes a third insulating layer disposed below the first insulating layer.

In addition, the adhesive member includes at least one of a conductive paste and a non-conductive paste.

In addition, the electrode part includes a via electrode penetrating the third insulating layer of the insulating layer and overlapping the connection member in the vertical direction.

In addition, the via electrode is electrically connected to the electrode pattern.

In addition, the metal layer of the connection member has a plurality of through holes, and the connection member includes a lower pad provided on a lower surface of the insulating part and disposed in the plurality of through holes.

In addition, an inner wall of the through hole of the metal layer is provided to surround a side surface of the lower pad at a position spaced apart from the lower pad in the horizontal direction, and at least a portion of the adhesive member is disposed between the inner wall of the through hole of the metal layer and the side surface of the lower pad.

In addition, the insulating part of the connection member is provided with an inorganic or organic material, and the metal layer is coated, deposited, or plated on the lower surface of the insulating part.

Meanwhile, a circuit board according to an embodiment comprises an insulating layer; a connection member embedded in the insulating layer; and an electrode part penetrating at least a portion of the insulating layer and overlapping the connection member in a vertical direction, wherein the connection member includes an insulating part; a plurality of upper pads disposed on an upper surface of the insulating part; and a metal layer disposed on a lower surface of the insulating part, wherein the electrode part includes a plurality of first via electrodes disposed under the connection member, commonly connected to the metal layer, and spaced apart from each other in the horizontal direction; and a plurality of second via electrodes disposed on the connection member and respectively connected to the plurality of upper pads.

In addition, a lower surface of the metal layer has a step, and the insulating layer contacts the step.

In addition, an upper surface of each of the plurality of first via electrodes is connected to a lower surface of the metal layer, and the first plurality of first via electrodes is not electrically connected to the upper pad of the connection member.

Meanwhile, a circuit board according to an embodiment comprises: an insulating layer; a connection member embedded in the insulating layer; a first electrode part disposed between a lower surface of the insulating layer and the connection member; a second electrode part disposed between an upper surface of the insulating layer and the connection member; a bonding part disposed on the second electrode part; and a semiconductor device disposed on the bonding part, wherein the connection member includes an insulating part; a plurality of upper pads disposed on an upper surface of the insulating part and connected to the second electrode part; a metal layer disposed on a lower surface of the insulating part and having a plurality of through holes; and a plurality of lower pads disposed on a lower surface of the insulating part and disposed in the plurality of through holes of the metal layer, wherein the first electrode part includes a first via electrode penetrating at least a portion of the insulating layer from the lower surface of the insulating layer and connected to the metal layer; and a second via electrode spaced apart from the first via electrode in a horizontal direction and connected to the plurality of lower pads.

### Advantageous Effects

A semiconductor package of an embodiment comprises a circuit board and a connection member embedded within the circuit board. The circuit board includes an insulating layer having a cavity, an electrode pattern formed in the cavity of the insulating layer, and an adhesive member disposed on the electrode pattern. In addition, the connection member includes a metal layer, and the metal layer of the connection member is disposed on the adhesive member.

That is, the embodiment provides a metal layer formed on a lower surface of the connection member, thereby enhancing adhesion between the insulating layer of the circuit board and the connection member. For example, the connection member may include an insulating material different from an insulating material of an insulating layer of the circuit board. A coefficient of thermal expansion of the connection member may differ from that of the insulating layer of the circuit board. Consequently, a difference in the coefficient of thermal expansion of the connection member and the coefficient of thermal expansion of the circuit board may cause the connection member to significantly warp in a specific direction. In this case, the metal layer of the connection member can enhance the rigidity of the connection member, thereby preventing the connection member from significantly warping in a specific direction.

In addition, the connection member can be attached to an adhesive member provided in the circuit board. If the connection member does not include a metal layer, the adhesive member may come into direct contact with the organic or inorganic material of the connection member. At this time, if the adhesive member and the organic or inorganic materials of the connection member come into direct contact, a problem of deteriorating adhesion may occur, and accordingly, the connection member may not be stably disposed on the adhesive member.

For example, if the connection member does not include a metal layer, separation between the adhesive member and the connection member may occur, and accordingly, a problem in which the connection member is peeled off from the adhesive member may occur.

Therefore, the connection member of the embodiment includes a metal layer, and the metal layer of the connection member can be attached to the adhesive member. The adhesion between the adhesive member and the metal layer is higher than the adhesion between the adhesive member and the inorganic or organic insulating material of the connection member, thereby ensuring the connection member is firmly attached to the adhesive member. Therefore, the embodiment can resolve the issue of the connection member peeling off from the adhesive member, thereby improving the physical and/or electrical reliability of the semiconductor package.

In addition, if the connection member does not have a metal layer, uniform pressure may not be applied to an entire region of the connection member during a process of attaching the connection member to the adhesive member, resulting in a deterioration in a flatness of the connection member. Furthermore, a deterioration in the flatness of the connection member may result in a height deviation between a plurality of pads of the connection member. Furthermore, a height deviation between the plurality of pads of the connection member may also result in a height deviation between electrode parts of the circuit board mounted on the connection member. Therefore, the semiconductor device may not be stably disposed on the circuit board, and as a result, the semiconductor device may not operate stably.

In addition, the metal layer of the connection member can stably secure and/or attach the connection member to the circuit board, thereby preventing movement or tilting of the connection member within the circuit board.

Exemplarily, expansion and/or contraction of the semiconductor package may occur due to heat during a process of manufacturing the semiconductor package and/or the operation of the semiconductor package. In this case, the metal layer can enhance the adhesion between the connection member and the circuit board, thereby improving the reliability of the semiconductor package from heat cycles such as expansion and/or contraction of the semiconductor package due to heat. For example, stress due to heat cycles such as expansion and/or contraction may be applied to the connection member, which may cause reliability issues such as misalignment of the connection member within the circuit board. If the connection member misaligns during a process of manufacturing the semiconductor package, an alignment between the pad part of the connection member and the second electrode part of the circuit board in a vertical direction may deteriorate, resulting in a problem such as a decrease in product yield. In addition, if the connection member misaligns during the operation of the semiconductor package, communication characteristics between a plurality of semiconductor devices through the connection member may be deteriorated, and thus the semiconductor device may not operate stably.

The connection member according to the embodiment may include a metal layer, which may increase the rigidity of the connection member while improving the adhesion between the connection member and the circuit board. Accordingly, the embodiment can prevent the connection member from tilting due to heat cycles such as expansion and/or contraction, thereby stably fixing and/or attaching the connection member to a designated location within the circuit board. Therefore, the embodiment can improve product yield and enable stable communication between a plurality of semiconductor devices via the connection member.

Therefore, the connection member of the embodiment includes a metal layer, and thus the metal layer of the connection member can provide uniform pressure to the entire region of the connection member during the process of attaching the connection member to the adhesive member. Accordingly, the embodiment can improve the flatness of the connection member, thereby ensuring that the plurality of pads provided in the connection member have uniform heights. Therefore, the embodiment can minimize height deviations between the plurality of electrode parts provided in the connection member. In addition, the embodiment may allow semiconductor devices to be stably disposed on the circuit board, thereby ensuring stable operation of the semiconductor device. Therefore, the embodiment can improve the operational reliability of semiconductor packages, and further, of products such as servers.

In addition, the embodiment may allow the metal layer of the electrode part provided in the circuit board and the connection member to be connected to each other. Accordingly, the embodiment uses the metal layer of the connection member to dissipate heat generated in the semiconductor device to a lower portion and/or side portion of the circuit board. Accordingly, the embodiment may improve heat dissipation characteristics of the semiconductor package, thereby allowing the semiconductor package to operate more stably.

Furthermore, a lower surface of the connection member of the embodiment may have a step, and thus the metal layer provided on the lower surface of the connection member may also have a step. Therefore, the embodiment may increase a contact area between the metal layer of the connection member and the adhesive member and/or insulating layer of the circuit board, thereby enabling more stable attachment of the connection member to the circuit board.

In addition, the adhesive member may not be provided between the electrode part provided in the circuit board of the embodiment and the metal layer of the connection member, and thus, the metal layer of the connection member may be directly connected to the electrode part provided in the circuit board. Accordingly, the embodiment can further improve the heat dissipation characteristics of the semiconductor package by directly connecting the metal layer of the electrode part and the connection member.

### DESCRIPTION OF DRAWINGS

FIG. 1 is a cross-sectional view illustrating a semiconductor package according to a first embodiment.

FIG. 2 is an enlarged cross-sectional view of a region R1 of FIG. 1.

FIG. 3 is a drawing illustrating a detailed layer structure of a connection member of FIG. 1 according to an embodiment.

FIG. 4 is an enlarged cross-sectional view of a region R1 of FIG. 1 according to a second embodiment.

FIGS. 5 and 6 are cross-sectional views illustrating a detailed layer structure of the connection member of FIG. 4.

FIG. 7 is a cross-sectional view illustrating a connection member of FIG. according to another embodiment.

FIG. 8 is a bottom view of a connection member of FIG. 7.

FIG. 9 is a cross-sectional view illustrating a semiconductor package according to a third embodiment.

FIG. 10 is an enlarged cross-sectional view of a region R1 of FIG. 7.

FIGS. 11 to 20 are cross-sectional views illustrating a method of manufacturing the semiconductor package shown in FIG. 1 in order of processes.

FIGS. 21 to 30 are cross-sectional views illustrating a method of manufacturing the semiconductor package shown in FIG. 9 in order of processes.

### BEST MODEL

Hereinafter, embodiments will be described in detail with reference to the accompanying drawings.

However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art. Further, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present invention, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements. Furthermore, when expressed as “on (over)” or “under (below)”, it may include not only the upper direction but also the lower direction based on one element.

### Electronic Device

The semiconductor package according to an embodiment may be applied to an electronic device. The main board may be connected to the semiconductor package of the embodiment. The semiconductor package may include at least one semiconductor device.

For example, a semiconductor device may include at least one of a central processor (CPU), a graphic processor (GPU), a digital signal processor, an encryption processor, a microprocessor, a microcontroller, an analog-to-digital converter, an application-specific IC (ASIC), an HBM, a volatile memory (e.g., DRAM), a non-volatile memory (e.g., ROM), and a flash memory. In addition, a semiconductor device may be a set of chips containing a specific combination of semiconductor devices listed so far.

In addition, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, a computer, a monitor, a tablet, a laptop, a netbook, a television, a video game, a smart watch, an automotive, or the like.

### Semiconductor Package

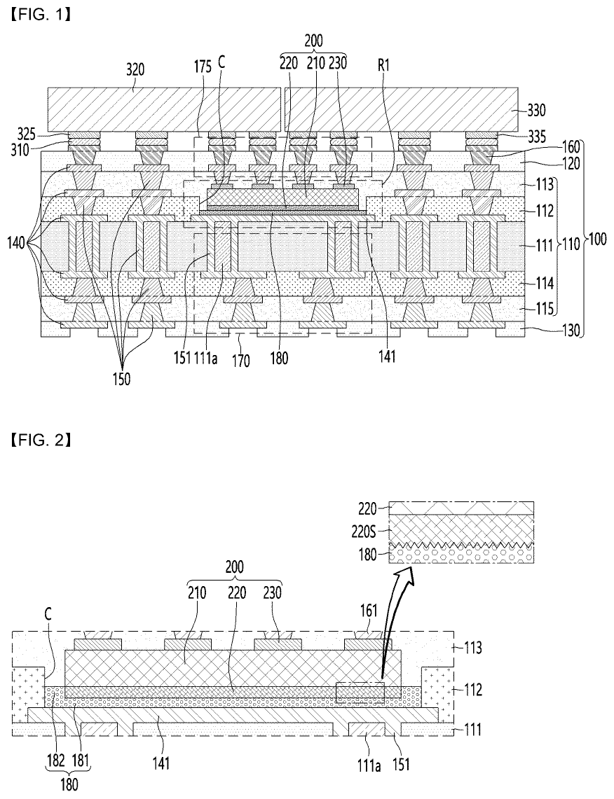

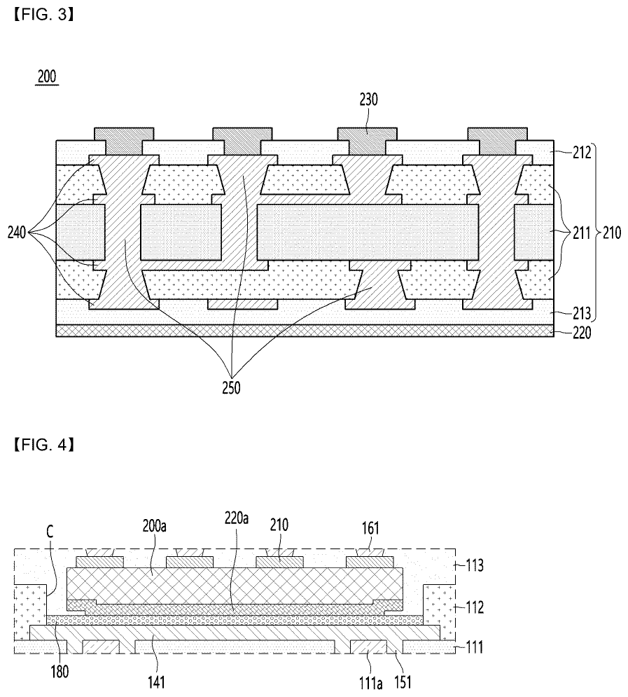

FIG. 1 is a cross-sectional view illustrating a semiconductor package according to a first embodiment, FIG. 2 is an enlarged cross-sectional view of a region R1 of FIG. 1, and FIG. 3 is a drawing illustrating a detailed layer structure of a connection member of FIG. 1 according to an embodiment.

Referring to FIGS. 1 and 2, a semiconductor package includes a circuit board 100, a connection member 200 embedded within the circuit board 100, and semiconductor devices 320 and 330 disposed on the circuit board 100.

In one embodiment, the circuit board 100 is disposed between a main board of an electronic device and the semiconductor devices 320 and 330, and can electrically couple them therebetween. In this case, the circuit board 100 can horizontally electrically connect the semiconductor devices 320 and 330 while vertically electrically connecting the semiconductor devices 320 and 330 and the main board of the electronic device.

In another embodiment, the circuit board 100 refers to a relay substrate (for example, an interposer) disposed between a package substrate and the semiconductor devices 320 and 330. That is, the circuit board 100 can horizontally electrically connect the semiconductor devices 320 and 330 while vertically electrically connecting the semiconductor devices 320 and 330 and the package substrate.

The semiconductor package includes semiconductor devices 320 and 330 disposed on the circuit board 100.

The semiconductor devices 320 and 330 may include a first semiconductor device 320 and a second semiconductor device 330, but are not limited thereto. For example, three or more semiconductor devices may be disposed on the circuit board 100, or one semiconductor device may be disposed.

The semiconductor package includes a bonding part 310 disposed between the semiconductor devices 320 and 330 and the circuit board 100.

The bonding part 310 electrically connects terminals 325 and 335 of the semiconductor device 320 and 330 to a bump part 160 of the circuit board 100.

The bonding part 310 electrically connects the bump part 160 of the circuit board 100 to the terminals 325 and 335 of the semiconductor device 320 and 330 using at least one bonding method, including wire bonding, solder bonding, and direct metal-to-metal bonding.

The wire bonding method electrically connects the bump part 160 of the circuit board to the terminals 325 and 335 of the semiconductor device 320 and 330 using a conductor such as gold (Au).

The solder bonding method electrically connects the bump part 160 of the circuit board 100 and the terminals 325 and 335 of the semiconductor device 320 and 330 using a material containing at least one of Sn, Ag, and Cu.

The direct metal-to-metal bonding method means applying heat and pressure between the bump part 160 of the circuit board 100 and the terminals 325 and 335 of the semiconductor device 320 and 330 to recrystallize without using solder, wires, conductive adhesives, etc., thereby directly bonding the bump part 160 of the circuit board 100 and the terminals 325 and 335 of the semiconductor device 320 and 330. Here, the bonding part 310 can be understood as a part that electrically connects the bump part 160 of the circuit board 100 and the terminals 325 and 335 of the semiconductor devices 320 and 330, rather than using solder or wire.

For example, the bonding part 310 can electrically connect the bump part 160 of the circuit board 100 and the terminals 325 and 335 of the semiconductor devices 320 and 330 using a thermal compression bonding method. The thermal compression bonding method can reduce a volume of the bonding part 310 and prevent short circuits between a plurality of bonding parts. Therefore, when the terminals 325 and 335 of the semiconductor devices 320 and 330 and/or the bump part 160 of the circuit board 100 have a fine pitch, the thermal compression bonding method may be advantageous.

The semiconductor package includes a connection member 200 embedded in a circuit board 100.

In one embodiment, the connection member 200 may be a bridge die. For example, the connection member 200 partially overlaps semiconductor devices 320 and 330 disposed on the circuit board 100 in a vertical direction.

In one embodiment, a plurality of connection members 200 may be provided in the circuit board. Thus, the plurality of connection members may enable mutual communication between at least three semiconductor devices disposed on the circuit board 100. For example, the at least three semiconductor devices may exchange electrical signals with each other through connecting members overlapping in the vertical direction.

The connection member 200 electrically connects a portion of a terminal 325 of a first semiconductor device 320 to a portion of a terminal 335 of a second semiconductor device 330.

For example, chiplet unit where semiconductor device is functionally separated, or a plurality of semiconductor devices 320 and 330 having different functions such as CPU and GPU, GPU and HBM may be mounted on the circuit board 100, and the connection member 200 can perform the function of horizontally electrically connecting them.

The connection member 200 includes an insulating part 210, a metal layer 220, and a pad part 230. The metal layer 220 of the connection member 200 is disposed on a lower surface of the insulating part 210 of the connection member 200. In addition, the pad part 230 of the connection member 200 is disposed on an upper surface of the insulating part 210 of the connection member 200. In this case, the drawing shows that the pad part 230 is disposed on the upper surface of the insulating part 210, but is not limited thereto. For example, the pad part 230 may be disposed on the upper and lower surfaces of the insulating part 210, respectively. For example, the pad part 230 may include an upper pad disposed on the upper surface of the insulating part 210 and a lower pad disposed on the lower surface of the insulating part 210. In this case, the metal layer 220 may be formed on the lower surface of the insulating part 210 while avoiding a region where the lower pad is disposed. For example, the metal layer 220 may have a plurality of through holes overlapping the lower pad in a vertical direction, and the lower pad may be disposed in the through holes of the metal layer 220.

At this time, when the pad part 230 of the connection member 200 includes an upper pad and a lower pad, power can be stably supplied to the connection member 200 and a semiconductor device electrically connected to the connection member 200.

In particular, a number of power and communication terminals in semiconductor packages applied to servers and/or HPCs (High Performance Computers) is increasing significantly. Accordingly, if the pad part 230 of the connection member 200 is provided only on one side of the insulating part 210, stable power supply to the connection member 200 and/or a plurality of semiconductor devices may be difficult due to a lack of the number of power supply lines and/or a limitation of power intensity, and the semiconductor package may not operate stably due to a lack of power of the connection member 200 and/or the semiconductor device.

In this case, if the pad part 230 of the connection member 200 includes upper and lower pads, the number of power supply lines or the power intensity can be increased. Therefore, the embodiment can ensure a stable power supply to the connection member 200 and/or the semiconductor devices, and further, may prevent a drop in power supplied to the connection member 200 and/or the semiconductor device through decoupling of a capacitor function.

In one embodiment, the connection member 200 may be an inorganic bridge. For example, the connection member 200 may be a silicon bridge. In this case, the insulating part 210 of the connection member 200 may be an inorganic material. For example, the insulating part 210 of the connection member 200 may have a same material as the semiconductor device 320 and 330. If the connection member 200 is an inorganic bridge, the connection member 200 may have a through silicon via (TSV) penetrating the insulating part 210, thereby electrically connecting the upper pad and the lower pad disposed on the upper and lower surfaces of the insulating part 210, respectively. At this time, if the connection member 200 includes an insulating part 210, a TSV penetrating the insulating part 210, and a pad part 230 including an upper pad and a lower pad connected through the TSV, the metal layer 220 of the connection member 200 may have a through hole, and the lower pad of the pad part 230 may be disposed in the through hole of the metal layer 220. At this time, a diameter, width, and/or planar area of the through hole of the metal layer 220 may be larger than a diameter, width, and/or planar area of the lower pad, and accordingly, the metal layer 220 and the lower pad may not be physically and/or electrically connected to each other. However, the embodiment is not limited thereto, and when the connection member 200 is an inorganic bridge, the connection member 200 may not have a TSV penetrating the insulating part 210, and the pad part 230 of the connection member 200 may be provided only on the upper surface of the insulating part 210 of the connection member 200. In this case, the metal layer 220 may not have a through hole and may be provided entirely on the lower surface of the insulating part 210.

In another embodiment, the connection member 200 is an organic bridge. For example, the insulating part 210 of the connection member 200 may include an organic material. The connection member 200 may include an insulating part 210 of an organic substrate in which the silicon substrate of the inorganic bridge is redisposed with an organic material. In this case, the insulating part 210 may include an organic material such as a photocurable resin, or an organic material such as a thermocurable resin. When the connection member 200 is an organic bridge, the upper pad and the lower pad of the pad part 230 provided on each of the upper and lower surfaces of the insulating part 210 can be electrically connected to each other through a through electrode penetrating the insulating part 210 of the connection member 200. At this time, when the connection member 200 includes the insulating part 210, the through electrode penetrating the insulating part 210, and the pad part 230 including the upper pad and the lower pad connected through the through electrode, the metal layer 220 of the connection member 200 can have a through hole, and the lower pad of the pad part 230 can be disposed within the through hole of the metal layer 220. At this time, a diameter, width, and/or planar area of the through hole of the metal layer 220 can be larger than a diameter, width, and/or planar area of the lower pad, and accordingly, the metal layer 220 and the lower pad may not be physically and/or electrically connected to each other. However, the embodiment is not limited thereto, and the pad part 230 of the connection member 200 may only include an upper pad provided on the upper surface of the insulating part 210. In this case, the metal layer 220 may not have a through hole and may be provided entirely on the lower surface of the insulating part 210.

The connection members 200 may be provided in multiple pieces and spaced horizontally within the circuit board 100. For example, the semiconductor package applied to servers, HPCs, etc. requires high power and/or multi-signal characteristics. Furthermore, the semiconductor package applied to servers, HPCs, etc. may have a plurality of mounted semiconductor devices. In this case, a plurality of connection members may be provided to be spaced apart from each other in the horizontal direction on the circuit board 100.

The connection member 200 includes a pad part 230. The pad part 230 of the connection member 200 is electrically connected to an electrode part of the circuit board 100. In particular, the electrode part of the circuit board 100 includes a wiring electrode 140, a via electrode 150, and a bump part 160. At this time, the wiring electrode 140, the via electrode 150, and the bump part 160 can be divided into a first electrode part 170 and a second electrode part 175 depending on their positions. The first electrode part 170 and the second electrode part 175 refer to electrodes that overlap the connection member 200 in the circuit board 100 in the vertical direction. At this time, the first electrode part 170 refers to electrodes disposed under the connection member 200 in the circuit board 100, and the second electrode part 175 refers to electrodes disposed on the connection member 200 in the circuit board 100.

At this time, when the pad part 230 of the connection member 200 has only an upper pad, the upper pad of the pad part 230 of the connection member 200 is electrically connected to the second electrode part 175 of the circuit board 100. In addition, when the pad part 230 of the connection member 200 has both an upper pad and a lower pad, the upper pad of the pad part 230 of the connection member 200 may be connected to the second electrode part 175, and the lower pad may be connected to the first electrode part 170.

The second electrode part 175 of the circuit board 100 is provided between the pad part 230 of the connection member 200 and the terminals 325 and 335 of the semiconductor device 320 and 330 in the circuit board 100. Accordingly, the pad part 230 of the connection member 200 is electrically connected to the terminals 325 and 335 of the semiconductor devices 320 and 330 through the second electrode part 175 and the bonding part 310. Therefore, the connection member 200 can horizontally electrically connect the terminals 325 and 335 of the semiconductor devices 320 and 330.

The connection member 200 includes a metal layer 220. The metal layer 220 is provided on the lower surface of the connection member 200. For example, the metal layer 220 is provided on the lower surface of the insulating part 210 of the connection member 200. The metal layer 220 may be provided on the lower surface of the connection member 200 through at least one of a coating, a deposition, and a plating method, but is not limited thereto.

The metal layer 220 may be provided on the lower surface of the connection member 200, and thus may function to improve an adhesion between an insulating layer 110 of the circuit board 100 and the connection member 200. For example, the connection member 200 may include an insulating material different from an insulating material of the insulating layer 110 of the circuit board 100. At this time, a coefficient of thermal expansion of the connection member 200 may be different from a coefficient of thermal expansion of the insulating layer 110 of the circuit board 100. Accordingly, the connection member 200 may be greatly warped in a specific direction due to the difference between the coefficient of thermal expansion of the connection member 200 and the thermal of thermal expansion of the circuit board 100. At this time, the metal layer 220 of the connection member 200 may improve the rigidity of the connection member 200, and thereby prevent the connection member 200 from being greatly warped in a specific direction.

In addition, the metal layer 220 can stably fix and/or attach the connection member 200 in the circuit board 100, thereby preventing the connection member 200 from moving or tilting within the circuit board 100.

For example, during a process of manufacturing the semiconductor package and/or the operation of the semiconductor package, heat may cause the semiconductor package to expand and/or contract. In this case, the metal layer 220 can improve the adhesion between the connection member 200 and the circuit board 100, thereby improving the reliability of the semiconductor package from heat cycles such as expansion and/or contraction of the semiconductor package due to heat. For example, stress due to heat cycles such as expansion and/or contraction may be applied to the connection member 200, resulting in reliability problems such as misalignment of the connection member 200 in the circuit board 100. At this time, if a position of the connection member 200 is misaligned during a process of manufacturing the semiconductor package, an alignment between the pad part 230 of the connection member 200 and the second electrode part 175 of the circuit board 100 in the vertical direction may deteriorate, resulting in problems such as a decrease in product yield. In addition, if the position of the connection member 200 is misaligned during the operation of the semiconductor package, the communication characteristics between a plurality of semiconductor devices through the connection member 200 may deteriorate, which may cause the semiconductor devices to not operate stably.

The connection member 200 according to the embodiment may include a metal layer 220, and by using the metal layer 220, the rigidity of the connection member 200 may be increased, while the adhesion between the connection member 200 and the circuit board 100 may be improved. Accordingly, the embodiment can prevent the connection member 200 from being tilted due to heat cycles such as expansion and/or contraction, thereby stably fixing and/or attaching the connection member 200 to a designated position within the circuit board 100. Accordingly, the embodiment can improve product yield and enable a plurality of semiconductor devices to stably communicate via the connection member 200.

For example, the connection member 200 can be attached to an adhesive member 180 provided in the circuit board 100. In this case, if the connection member 200 does not include a metal layer 220, the adhesive member 180 may be in direct contact with the insulating part 210 of the connection member 200. At this time, if the adhesive member 180 and the insulating part 210 of the connection member 200 are in direct contact, a problem of deteriorating adhesion may occur, and accordingly, the connection member 200 may not be stably disposed on the adhesive member 180. Alternatively, a lifting may occur between the adhesive member 180 and the connection member 200, and thus the connection member 200 may be peeled off from the adhesive member 180.

That is, the adhesion between the adhesive member 180 and the metal layer 220 is higher than the adhesion between the adhesive member 180 and the insulating part 210 of the connection member 200, and thus the connection member 200 can be firmly attached to the adhesive member 180. Accordingly, the embodiment can solve the problem of the connection member 200 being peeled off from the adhesive member 180 and the problem of the connection member 200 being misaligned during the semiconductor package manufacturing process and/or operation. Therefore, the embodiment can improve the physical reliability and/or electrical reliability of the semiconductor package.

In addition, if the connection member 200 is not provided with a metal layer 220, uniform pressure may not be applied to an entire region of the connection member 200 during the process of attaching the connection member 200 onto the adhesive member 180, and thus a flatness of the connection member 200 may be reduced. For example, if the connection member 200 is not provided with a metal layer 220, the connection member 200 may be damaged by the pressure applied during the process of attaching the connection member 200. Accordingly, if the metal layer 220 is not provided in the connection member 200, the pressure intensity must be reduced under conditions where the connection member 200 is not damaged, and as a result, uniform pressure cannot be provided to the entire region of the connection member 200, which may result in a decrease in flatness. In addition, when the flatness of the connection member 200 is decreased, a height deviation of the plurality of pad parts 230 of the connection member 200 (for example, a height deviation of upper surfaces of the plurality of upper pads) may occur. In addition, when a height deviation of the pad parts 230 of the connection member 200 occurs, a height deviation of electrode parts of the circuit board 100 provided on the connection member 200 may occur. Therefore, the semiconductor device may not be stably disposed on the circuit board 100, and thus, the semiconductor device may not operate stably.

Accordingly, the connection member 200 according to the embodiment has a metal layer 220, and through this, the flatness of the connection member 200 can be improved. For example, when the metal layer 220 is provided in the connection member 200, the strength of the pressure applied during the attachment process of the connection member 200 can be increased, and thus, a uniform pressure can be provided to the entire region of the connection member 200. Through this, the embodiment can improve the flatness of the connection member 200, and thus, the plurality of pad parts 230 provided on the connection member 200 can have a uniform height. Therefore, the embodiment can minimize the height deviation of the second electrode parts 175 provided on the connection member 200. Furthermore, the embodiment can enable a semiconductor device to be stably disposed on a circuit board 100, and thus, the semiconductor device can be stably operated. Accordingly, the embodiment can improve the operational reliability of the semiconductor package, and further improve the operational reliability of products such as servers.

In addition, the embodiment can connect the first electrode part 170 of the circuit board 100 and the metal layer 220 of the connection member 200 to each other. Thus, the embodiment uses the metal layer 220 of the connection member 200 to dissipate heat generated in the semiconductor device 320 and 330 and/or the connection member 200 to the lower portion and/or the side portion of the circuit board 100. For example, the first electrode part 170 provided in the circuit board 100 is disposed under the connection member 200 and is connected to the metal layer 220 of the connection member 200. At this time, the first electrode part 170 is connected to the metal layer 220 of the connection member 200, and thus can function as a heat dissipation electrode that dissipate heat generated from the connection member 200 and/or the semiconductor device 320 and 330 to the side portion and/or lower portion of the circuit board 100. Through this, the embodiment can improve the heat dissipation characteristics of the semiconductor package, thereby enabling the semiconductor package to operate more stably.

In addition, the lower surface of the metal layer 220 of the connection member 200 may be provided with a convexo-concave portion 220S. For example, the lower surface of the metal layer 220 of the connection member 200 may be provided with a surface roughness of a certain level or higher. In an embodiment, the convexo-concave portion 220S may be provided on the lower surface of the metal layer 220 of the connection member 200, and through this, the adhesion between the metal layer 220 of the connection member 200 and the adhesive member 180 may be further improved.

In this case, the metal layer 220 of the connection member 200 may not be electrically connected to the pad part 230 of the connection member 200. For example, the metal layer 220 of the connection member 200 may be insulated from the pad part 230 of the connection member 200. Therefore, the embodiment can improve the electrical reliability and/or physical reliability of a semiconductor package by utilizing the metal layer 220 of the connection member 200 without affecting the electrical connection reliability of multiple semiconductor devices via the connection member 200. A detailed layer structure of the connection member 200 and various embodiments thereof will be described in more detail below.

The circuit board 100 includes an insulating layer 110. For example, the circuit board 100 includes an insulating layer 110 that embeds the connection member 200.

The insulating layer 110 may include an organic material that does not include a reinforcing member, which allows for excellent processability, slimming of the board, and miniaturization of the wiring electrode 140 and/or via electrode 150 provided in the circuit board. For example, the insulating layer 110 of the circuit board can utilize ABF (Ajinomoto Build-up Film), a product released by Ajinomoto, as an example, FR-4, Bismaleimide Triazine (BT), and Photo Image-able Dielectric Resin (PID) may be used.

The insulating layer 110 may be formed by stacking multiple layers. For example, as illustrated in FIG. 1, the insulating layer 110 may include first to fifth layers 111, 112, 113, 114, and 115, but the embodiment is not limited thereto.

In one embodiment, a plurality of layers of the insulating layer 110 may be formed of a same insulating material. However, the embodiment is not limited thereto, and at least one of the plurality of layers of the insulating layer 110 may include an insulating material different from the other layers.

Through the laminated structure of the insulating layer 110 described above, the circuit board of the embodiment can electrically connect the semiconductor device 320 and 330 and the package substrate and/or main board.

At least one of the plurality of layers of the insulating layer 110 of one embodiment may include a reinforcing member. In one embodiment, the reinforcing member may be glass fiber. In another embodiment, the reinforcing member may be GCP (Glass Core Primer). When the reinforcing member is glass fiber, at least one of the plurality of layers of the insulating layer 110 serves as a core layer, thereby providing the circuit board as a core substrate.

Furthermore, by including at least one of the plurality of layers of the insulating layer 110 with a reinforcing member, the rigidity of the circuit board can be improved. For example, the reinforcing member may function to prevent the circuit board and semiconductor package from being significantly warped in a specific direction. Accordingly, the insulating layer 110 can be prevented from warping during the manufacturing process of the circuit board, thereby improving the positional accuracy of the wiring electrode 140 and the via electrode 150, and further improving the alignment between them. In addition, as the rigidity of the circuit board is secured, the semiconductor devices 320 and 330 can be coupled to the circuit board, and the semiconductor devices 320 and 330 can be operated stably. Furthermore, electronic products such as servers to which the semiconductor package of the embodiment is applied can be operated stably, and thus product reliability can be improved.

For example, the insulating layer 110 is provided with first to fifth layers 111, 112, 113, 114, and 115, and the first layer 111 among the first to fifth layers 111, 112, 113, 114, and 115 may be a core layer including a reinforcing member. At this time, the second to fifth layers 112, 113, 114, and 115, excluding the first layer 111, may not include a reinforcing member.

In addition, if at least one of the plurality of layers of the insulating layer 110 includes a reinforcing member, a filling portion 111a is provided in the first layer 111 of the insulating layer 110 including the reinforcing member. The filling portion 111a penetrates the first layer 111 of the insulating layer 110 including the reinforcing member. The filling portion 111a may be formed using hole plugging ink, but is not limited thereto. The filling portion 111a is surrounded by a via electrode 151 penetrating the first layer 111a of the insulating layer 110 including the reinforcing member.

That is, when the first layer 111 of the insulating layer 110 is thick, a problem may arise in which the via electrode 151 penetrating the first layer 111 cannot densely fill the through hole of the first layer 111. Accordingly, a problem may arise in which the upper or lower surface of the via electrode 151 cannot be plated flatly, and a void may occur inside the via electrode 151. Accordingly, the arrangement of the filling portion 111a can solve electrical reliability problems and/or mechanical reliability problems that may arise due to the through hole of the first layer 111 including the reinforcing member not being entirely filled by the via electrode 151.

At least one of the first to fifth layers 111, 112, 113, 114, and 115 of the insulating layer 110 has a cavity C. For example, the cavity C may penetrate at least one of the first to fifth layers 111, 112, 113, 114, and 115 of the insulating layer 110. In addition, the cavity C may be embedded by at least one of the first to fifth layers 111, 112, 113, 114, and 115. For example, the cavity C in the first embodiment may be provided penetrating the second layer 112 of the insulating layer 110. At this time, a connection member 200 may be disposed in the cavity C provided in the second layer 112 of the insulating layer 110. In addition, the third layer 113 of the insulating layer 110 may be provided to fill the cavity C, and thus may be provided to surround a side portion of the connection member 200.

The circuit board 100 includes a first protective layer 120 disposed on an insulating layer 110. In addition, the circuit board 100 includes a second protective layer 130 disposed under the insulating layer 110. For example, the first protective layer 120 may be disposed on a third layer 113 disposed on an uppermost side among the plurality of layers of the insulating layer 110. For example, the second protective layer 130 may be disposed under a fifth layer 115 disposed on a lowermost side among the plurality of layers of the insulating layer 110.

The first protective layer 120 and the second protective layer 130 have poor wettability with solder, so the first protective layer 120 and the second protective layer 130 can protect the circuit board 100 from electrical short-circuit problems caused by contact between solders disposed on the electrode parts of the circuit board 100, and protect the insulating layer 110 from external contaminants such as moisture or particles that may be exposed during the manufacturing process of the circuit board 100.

Each of the first protective layer 120 and the second protective layer 130 may include at least one through hole. For example, the first protective layer 120 may include a through hole overlapping the bump part 160 in a vertical direction. In addition, the second protective layer 130 may include a through hole overlapping a wiring electrode disposed at the lowest side among the wiring electrodes 140, in the vertical direction.

The first protective layer 120 and the second protective layer 130 may be solder resist layers containing organic polymer materials. For example, the first protective layer 120 and the second protective layer 130 may include an epoxy acrylate-based resin. Specifically, the first protective layer 120 and the second protective layer 130 may include resins, curing agents, photo initiators, pigments, solvents, fillers, additives, acrylic-based monomers, and the like. However, the embodiment is not limited thereto, and the first protective layer 120 and the second protective layer 130 may be any one of a photo solder resist layer, a cover-lay, and a polymer material.

The circuit board 100 includes an electrode part. The electrode part 100 includes a wiring electrode 140, a via electrode 150, and a bump part 160 depending on locations and functions.

The wiring electrode 140 may be horizontally disposed between each of the plurality of layers of the insulating layer 110, and the via electrode 150 may be vertically disposed to penetrate each of the plurality of layers of the insulating layer 110. The bump part 160 may be provided on an uppermost wiring electrode among the wiring electrodes 140. The bump part 160 may penetrate the first protective layer 120.

The wiring electrode 140 may include an electrode pattern 141. The electrode pattern 141 may refer to an electrode among the wiring electrodes 140 provided on each surface of the insulating layer 110 that overlaps the connection member 200 in the vertical direction and is disposed closest to the metal layer 220 of the connection member 200. For example, the electrode pattern 141 may refer to an electrode among the wiring electrodes 140 that contacts the adhesive member 180. For example, the electrode pattern 141 may refer to an electrode facing the metal layer 220 of the connection member 200 with the adhesive member 180 therebetween. The electrode pattern 141 may overlap the connection member 200 in the vertical direction. For example, the metal layer 220 may be disposed on a bottom surface of the cavity C provided in the insulating layer 110. The electrode pattern 141 may be connected to the metal layer 220 of the connection member 200 with the adhesive member 180 therebetween. For example, the electrode pattern 141 may be connected to the metal layer 220 of the connection member 200 via the adhesive member 180.

For example, the adhesive member 180 may be in contact with an upper surface of the electrode pattern 141, and the metal layer 220 of the connection member 200 may be in contact with the upper surface of the adhesive member 180.

Therefore, the embodiment may allow the adhesive member 180 to be disposed on the electrode pattern 141, thereby ensuring that the adhesive member 180 has a uniform thickness in a region between the electrode pattern 141 and the metal layer 220 of the connection member 200. For example, during the process of attaching the connection member 200 to the adhesive member 180, the electrode pattern 141 can apply uniform pressure to the entire region of the connection member 200 together with the metal layer 220 of the connection member 200, thereby ensuring the flatness of the connection member 200 while improving the adhesion between the connection member 200 and the adhesive member 180.

At this time, a width of the electrode pattern 141 in the horizontal direction can be greater than a width of the adhesive member 180 in the horizontal direction. In addition, the width of the electrode pattern 141 in the horizontal direction may be greater than a width of the connection member 200 in the horizontal direction. Preferably, the width of the electrode pattern 141 in the horizontal direction may be greater than the width of the metal layer 220 of the connection member 200 in the horizontal direction. Through this, the embodiment can allow the electrode pattern 141 of the connection member 200 to be more firmly adhered to the adhesive member 180 through the electrode pattern 141, thereby further improving the adhesive strength between the adhesive member 180 and the connection member 200.

In addition, the via electrode 150 includes a via part 151 that is provided under the connection member 200, overlaps the electrode pattern 141 in the vertical direction and is connected to the electrode pattern 141. For example, the via part 151 may be provided to penetrate at least a portion of the insulating layer 110, and an upper surface of the via part 151 may be connected to the lower surface of the electrode pattern 141. The via part 151 may function as a heat dissipation part that dissipate heat transmitted through the connection member 200 to the side portion and/or lower portion of the circuit board 100.

In addition, the bump part 160 may be disposed on an uppermost electrode among the wiring electrodes 140. The bump part 160 penetrates at least a portion of the first protective layer 120. For example, the bump part 160 may be disposed in a through hole of the first protective layer 120.

That is, the bump part 160 protrudes on the first protective layer 120 of the circuit board to stably bond with the terminals 325 and 335 of the semiconductor device 320 and 330 using the bonding part 310. This allows the bump part 160 to maintain a certain distance between the bonding part 310 and the circuit board, thereby improving the positional alignment between the bump part 160 and the terminals of the semiconductor device 320 and 330. The bump part 160 may be a post bump connected to the semiconductor device.

That is, as a width and a pitch of terminals of the semiconductor device bonded to the circuit board become smaller, when mounting the semiconductor device using a conductive adhesive such as solder, the conductive adhesive may diffuse in a horizontal direction, as a result, a problem in which a plurality of conductive adhesives are connected to each other may occur. For example, in an embodiment, thermal compression bonding may be performed to reduce the volume of the conductive adhesive. At this time, if the bump part 160 is not provided, it may be difficult for the conductive adhesive to reduce the volume of the conductive adhesive. This may be because a height of the electrode on which the conductive adhesive is disposed is positioned lower than the upper surface of the first protective layer 120, and thus the volume of the conductive adhesive increases by the difference in height between the electrode and the first protective layer 120.

In particular, as the width and pitch of the terminals 325 and 335 of the semiconductor devices 320 and 330 are becoming smaller, and when a conductive adhesive such as solder is applied to mount the semiconductor devices 320 and 330 without a bump part 160, a short circuit problem may occur in which two adjacent conductive adhesives are connected to each other as a spacing between the conductive adhesives becomes smaller. Therefore, the embodiment performs a process of mounting the semiconductor devices 320 and 330 by providing a bump part 160 and applying a conductive adhesive such as solder on the bump part 160. Preferably, the embodiment may perform thermal compression bonding using the bump part 160 protruding to an outermost side of the circuit board. Accordingly, the embodiment can stably mount the semiconductor device on the circuit board, and thereby enable the semiconductor device to operate stably.

At this time, the embodiment can provide a metal layer 220 on the connection member 200, thereby minimizing the height deviation of the plurality of pad parts 230 of the connection member 200, further minimizing the height deviation of the wiring electrode 140 and the via electrode 150 provided on the pad of the connection member 200, and further minimizing the height deviation of the bump part 160. Through this, the embodiment can allow the semiconductor device to be more stably disposed on the bump part 160, and furthermore, can allow the semiconductor device to operate more stably.

At this time, the electrode part of the circuit board 100 including the wiring electrode 140, the via electrode 150, and the bump part 160 can include a first electrode part 170 and a second electrode part 175 that overlap with the connection member 200 in the vertical direction. At this time, the electrode pattern 141 and the via part 151 may be included in the first electrode part 170.

In the circuit board 100, the first electrode part 170 may refer to electrodes disposed under the connection member 200 while overlapping the connection member 200 in the vertical direction. The first electrode part 170 may be connected to the metal layer 220 of the connection member 200 via the adhesive member 180. At this time, the first electrode part 170 may not be electrically connected to the pad part 230 of the connection member 200. The first electrode part 170 may function as a heat dissipation electrode that dissipates heat generated in the connection member 200 and/or the semiconductor device 320 and 330 via the metal layer 220 of the connection member 200. In addition, the second electrode part 175 may refer to electrodes disposed on the connection member 200 while overlapping the connection member 200 in the vertical direction. The second electrode part 175 may be electrically connected to the pad part 230 of the connection member 200. The second electrode part 175 may be provided between the pad part 230 of the connection member 200 and terminals of the semiconductor device 320 and 330, thereby electrically connecting them.

In addition, an adhesive member 180 is provided between the electrode pattern 141 of the circuit board 100 and the metal layer 220 of the connection member 200. The adhesive member 180 may provide a bonding force so that the metal layer 220 of the connection member 200 is bonded and/or fixed on the electrode pattern 141.

A width of the adhesive member 180 in the horizontal direction may be smaller than a width of the electrode pattern 141 in the horizontal direction. For example, the lower surface of the adhesive member 180 may be in contact with the electrode pattern 141 as a whole. This may further enhance the adhesion between the adhesive member 180 and the electrode pattern 141.

Furthermore, the width of the adhesive member 180 in the horizontal direction may be larger than the width of the metal layer 220 of the connection member 200. This may allow the metal layer 220 to be more stably adhered to the adhesive member 180.

The adhesive member 180 may include a first portion 181 and a second portion 182. The first portion 181 and the second portion 182 of the adhesive member 180 may have different thicknesses. The first portion 181 of the adhesive member 180 may overlap the connection member 200 in the vertical direction. The second portion 182 of the adhesive member 180 may not overlap with the connection member 200 in the vertical direction. The second portion 182 of the adhesive member 180 may be a portion that extends toward a side surface of the connection member 200 by applying pressure after the metal layer 220 of the connection member 200 is disposed on the adhesive member 180. Accordingly, the first portion 181 and the second portion 182 of the adhesive member 180 may have different thicknesses. The second portion 182 of the adhesive member 180 may be provided to surround at least a portion of the side surface of the connection member 200. For example, the second portion 182 of the adhesive member 180 may be in contact with the side surface of the metal layer 220 of the connection member 200. Therefore, the embodiment can further improve the adhesion between the metal layer 220 of the connection member 200 and the adhesive member 180.

The adhesive member 180 may be a non-conductive paste, but is not limited thereto. For example, the adhesive member 180 may be a conductive paste, which may be used to connect the metal layer 220 of the connection member 200 and the electrode pattern 141 of the circuit board 100. This allows the embodiment to further improve the heat dissipation characteristics of the connection member 200.

Hereinafter, a detailed layer structure of the connection member 200 according to each embodiment will be described.

In this case, the connection member 200 may be an inorganic bridge, as described above, or an organic bridge. Furthermore, the pad part 230 of the connection member 200 may be disposed on only one surface of the insulating part 210 of the connection member 200, or on both surfaces of the insulating part 210. A following description will be given in detail regarding the case where the connection member 200 is an organic bridge. However, the embodiment is not limited thereto, and the connection member 200 may be provided as an inorganic bridge.

Referring to FIG. 3, the connection member 200 may include an insulating part 210, a metal layer 220, and a pad part 230. Furthermore, the connection member 200 may further include a circuit part 240 and 250 provided on an inner layer of the insulating part 210. The circuit part 240 and 250 may include a wiring part 240 provided on the surface of each layer of the insulating part 210 and a via part 250 penetrating at least a portion of the insulating part 210 and connected to the wiring part 240.

The insulating part 210 may include an inner insulating part 211, an upper insulating part 212, and a lower insulating part 213. The inner insulating part 211 may have a multi-layer structure along a thickness direction. For example, as illustrated in FIG. 3, the inner insulating part 211 may have a three-layer structure, but is not limited thereto.

The inner insulating part 211 may have properties that enable it to form a wiring part 240 of a connection member 200 including a fine electrode pattern. For example, the inner insulating part 211 may include an insulating material having excellent processability and elasticity. For example, the inner insulating part 211 may include polyimide (PI). Here, if the inner insulating part 211 of the connection member 200 is formed of an organic material, a difference in coefficient of thermal expansion between the inner insulating part 211 and the insulating layer 110 of the circuit board 100 can be reduced, thereby minimizing thermal deformation of the connection member 200 caused by the difference in coefficient of thermal expansion. For example, the embodiment allows the inner insulating part 211 of the connection member 200 to also flex when the insulating layer 110 of the circuit board 100 undergoes thermal deformation, thereby improving the physical and/or electrical reliability of the connection member 200. Furthermore, an organic bridge can lower processing costs and material costs compared to an inorganic bridge, thereby lowering the overall product price.

Furthermore, the connection member 200 can be provided with vias of relatively small widths. The alignment between multiple vias provided on different layers of the connection member 200 can significantly affect the operating characteristics of the connection member 200, the operating characteristics of the semiconductor package, and the operating characteristics of electronic products or servers to which the semiconductor package is applied. In this case, the polyimide may be transparent. Accordingly, the embodiment can improve the alignment of multiple vias provided on different layers. This can further improve the operating characteristics of the connection member 200, the operating characteristics of the semiconductor package, and the operating characteristics of electronic products or servers to which the semiconductor package is applied.

The upper insulating part 212 may be disposed on the inner insulating part 211, and the lower insulating part 213 may be disposed under the inner insulating part 211.

The upper insulating part 212 and the lower insulating part 213 may also be referred to as protective parts. For example, the upper insulating part 212 and the lower insulating part 213 may function to protect the connection member 200 from contaminants such as moisture or particles generated during the manufacturing process. For example, the upper insulating part 212 and the lower insulating part 213 may be solder resist.

The connection member 200 includes a wiring part 240 and a via part 250. The wiring part 240 may be provided in a horizontal direction on the surface of each layer of the inner insulating part 211. The via part 250 may be provided to penetrate each layer of the inner insulating part 211 and may be connected to the wiring part 240. The wiring part 240 and the via part 250 may correspond to the wiring electrode 140 and the via electrode 150 of the circuit board 100, respectively. However, the wiring part 240 of the connection member 200 may have a smaller width and pitch than the wiring electrode 140 of the circuit board 100, and the via part 250 of the connection member 200 may have a smaller width and pitch than the via electrode 150 of the circuit board 100.

The connection member 200 includes a pad part 230. As shown in FIG. 3, the pad part 230 in one embodiment may include only an upper pad. For example, the pad part 230 may be provided to penetrate the upper insulating part 212. The pad part 230 may be provided on an uppermost wiring part among the wiring parts 240 provided in each layer of the inner insulating part 211.

The metal layer 220 of the connection member 200 may be provided on the lower surface of the lower insulating part 213 of the connection member 200. For example, the metal layer 220 of the connection member 200 may be formed on the lower surface of the lower insulating part 213 by at least one of deposition, coating, and plating.

At this time, as shown in FIG. 3, the pad part 230 of the connection member 200 in one embodiment may only have an upper pad. In this case, the metal layer 220 of the connection member 200 may be formed entirely on the lower surface of the lower insulating part 213. For example, a planar area of the metal layer 220 may be the same as a planar area of the lower insulating part 213.

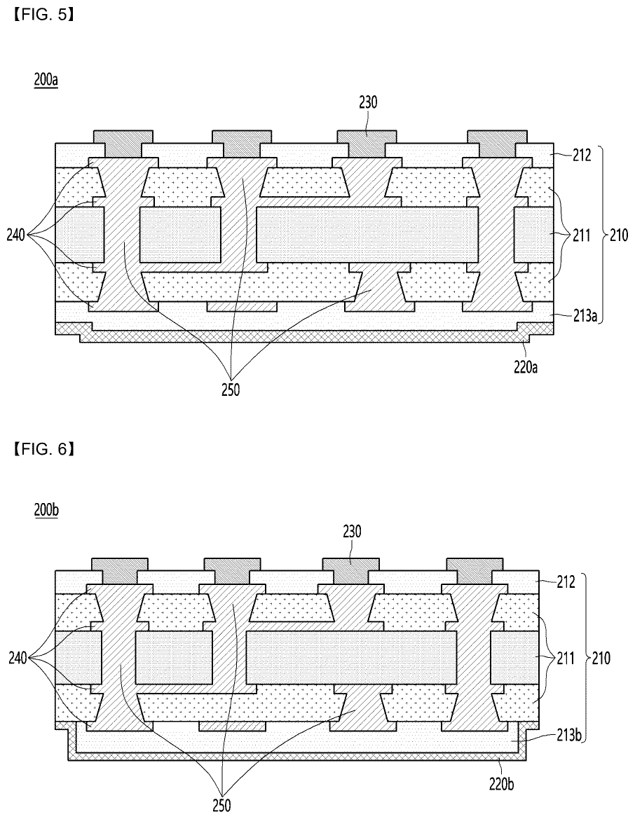

FIG. 4 is an enlarged cross-sectional view of a region R1 of FIG. 1 according to a second embodiment, and FIGS. 5 and 6 are cross-sectional views illustrating a detailed layer structure of the connection member of FIG. 4.

Referring to FIG. 4, a lower surface of the connection member 200a may have a step. For example, the connection member 200a may have a concave portion provided on at least a portion of the lower surface of the connection member and extending from the lower surface toward the upper surface of the connection member.

In addition, the metal layer 220a of the connection member 200a may have a step. For example, the metal layer 220a of the connection member 200a may be provided along the step of the lower surface of the connection member 200a, and thus may have a step corresponding to the step of the lower surface of the connection member 200a. In this case, if the connection member 200a is an organic bridge, the step of the lower surface of the connection member 200a may be provided on the lower surface of the insulating part 210. For example, the step of the lower surface of the connection member 200a may be provided on the lower insulating part and/or the inner insulating part.

It may be provided on a lower protective member and/or an insulating member.

For example, referring to FIG. 5, a lower surface of a lower insulating part 213a of the connection member 200a may have a step. At this time, the metal layer 220a of the connection member 200a may be disposed on the lower surface of the lower insulating part 213a. At this time, the lower surface of the lower insulating part 213a of the connection member 200a may have a step, and accordingly, the metal layer 220a of the connection member 200a may also have a step corresponding to the lower insulating part 213a. Through this, a surface area of the metal layer 220a of the connection member 200a can be further increased, and thus the adhesion between the connection member 200a and the adhesive member 180 can be further improved. Furthermore, at least a portion of the metal layer 220a may not be in contact with the adhesive member 180. For example, the metal layer 220a may include a separation portion spaced apart from the adhesive member 180 by a step, and the separation portion may be filled with the insulating layer 110 of the circuit board 100. In this case, the separation portion may function as an anchor to increase the bonding strength between the insulating layer 110 and the connection member 200a, thereby allowing the connection member 200a to be more firmly bonded within the insulating layer 110 of the circuit board 100.

Meanwhile, although FIG. 4 illustrates that the step of the connection member 200a and the first layer 113 of the insulating layer of the circuit board 100 are in contact, the embodiment is not limited thereto. For example, the upper surface of the adhesive member 180 may have a step corresponding to the step of the connection member 200a. For example, the lower surface of a connection member 200a having a step may be in contact with the adhesive member 140 as a whole.

In addition, referring to FIG. 6, the step of the lower surface of the connection member 200b may refer to the step between the lower surface of the inner insulating part 211 and the lower surface of the lower insulating part 213b. For example, a width of the inner insulating part 211 of the connection member 200b in the horizontal direction may be different from a width of the lower insulating part 213b in the horizontal direction. Accordingly, a side surface of the inner insulating part 211 of the connection member 200b may have a step from a side surface of the lower insulating part 213b.

Accordingly, the lower surface of the connection member 200b may be formed by a portion of the inner insulating part 211 and a portion of the lower insulating part 213b. Accordingly, the metal layer 220b of the connection member 200b may be provided on the lower surface of the lower insulating part 213b, the side surface of the lower insulating part 213b, and the lower surface of the inner insulating part 211, respectively, thereby providing a step.

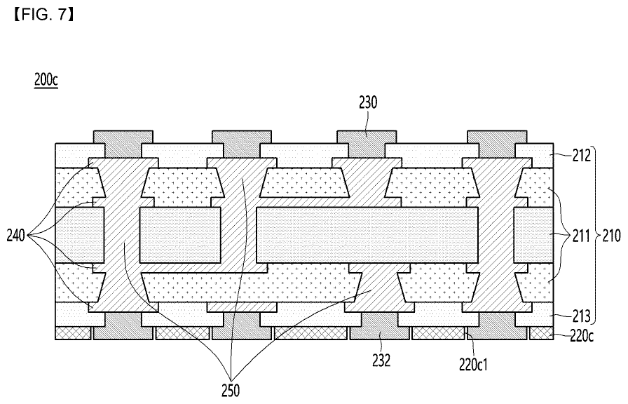

FIG. 7 is a cross-sectional view illustrating a connection member of FIG. 1 according to another embodiment, and FIG. 8 is a bottom view of a connection member of FIG. 7.

Referring to FIGS. 7 and 8, the connection member 200c may include an insulating part 210. The insulating part 210 may include an inner insulating part 211, an upper insulating part 212, and a lower insulating part 213. In addition, the connection member 200c may include a wiring part 240 and a via part 250.

Here, the inner insulating part 211, upper insulating part 212, lower insulating part 213, wiring part 240, and via part 250 may have substantially the same structure as the previous embodiment, and thus, a detailed description thereof will be omitted.

The connection member 200c includes a pad part. The pad part of the connection member 200c includes an upper pad 231 and a lower pad 232. For example, the upper pad 231 may be provided to penetrate the upper insulating part 212. Furthermore, the connection member 200c may further include a lower pad 232 that penetrates the lower insulating part 213.

At this time, the pad part 230 of the connection member 200c may include an upper pad 231 and a lower pad 232, thereby stably receiving power from the circuit board and further stably supplying power to the semiconductor device.

In particular, the number of power terminals and communication terminals in semiconductor packages applied to servers and/or HPCs (High Performance Computers) is increasing significantly. In this case, if the pad part of the connection member 200c only includes an upper pad 231, stable power supply to the connection member 200c and/or multiple semiconductor devices may be difficult due to insufficient power supply lines and/or limited power levels. Furthermore, the semiconductor package may not operate reliably due to insufficient power to the connection member 200c and/or semiconductor devices.

In this case, the connection member 200c may include an upper pad 231 and a lower pad 232, thereby enabling power supply through the lower pad 232. Therefore, the embodiment can increase the number of power supply lines or increase power levels. Accordingly, the embodiment can ensure a stable power supply to the connection member 200c and/or the semiconductor device, and further prevent a drop in power supplied to the connection member 200 and/or the semiconductor device through decoupling of the capacitor function.

Furthermore, the embodiment can improve the rigidity of the connection member 200c by including an upper pad 231 and a lower pad 232. Furthermore, the embodiment can prevent the connection member 200c from being significantly warped in a specific direction due to an asymmetrical structure of upper and lower portions of the connection member 200c by symmetrically arranging the pad parts on both surfaces of the connection member 200c, thereby enabling more stable operation of the semiconductor package.

The metal layer 220c may be disposed on the lower surface of the lower insulating part 213. The metal layer 220c may be partially disposed on the lower surface of the lower insulating part 213.

For example, a lower pad 232 is disposed on the lower surface of the lower insulating part 213. At this time, the metal layer 220c may be selectively disposed in a partial region of the lower surface of the lower insulating part 213 where the lower pad 232 is not disposed. In addition, the metal layer 220c may not be connected to the lower pad 232. For example, the metal layer 220c may not overlap the lower pad 232 in the vertical direction.

That is, referring to (a) of FIG. 8, the metal layer 220c may have a through hole 220c1 that overlaps the lower pad 232 in the vertical direction, and the lower pad 232 may be disposed in the through hole 220c1 of the metal layer 220c.

At this time, at least one of a width, diameter, and planar area of the through hole 220c1 of the metal layer 220c may be larger than at least one of a width, diameter, and planar area of the lower pad 232. For example, an inner wall of the through hole 220c1 of the metal layer 220c may be formed to surround the side surface of the lower pad 232 without contacting the side surface of the lower pad 232.

Therefore, a space may be formed between the inner wall of the through hole 220c1 of the metal layer 220c and the side surface of the lower pad 232. Additionally, as illustrated in (b) of FIG. 8, the space between the inner wall of the through hole 220c1 of the metal layer 220c and the side surface of the lower pad 232 may be filled with an adhesive member 180. For example, the adhesive member 180 may surround the side surface of the lower pad 232 and fill the through hole 220c1 of the metal layer 220c.

As such, the connection member 200c may include an upper pad 231 and a lower pad 232, thereby enabling power supply through the lower pad 232. Furthermore, the adhesive member 180 may be disposed in the through hole 220c1 of the metal layer 220c and surround the side surface of the lower pad 232. Therefore, the embodiment can further enhance the adhesion between the metal layer 220 and the adhesive member 280, thereby enabling the connection member 200c to be more stably fixed and/or attached.

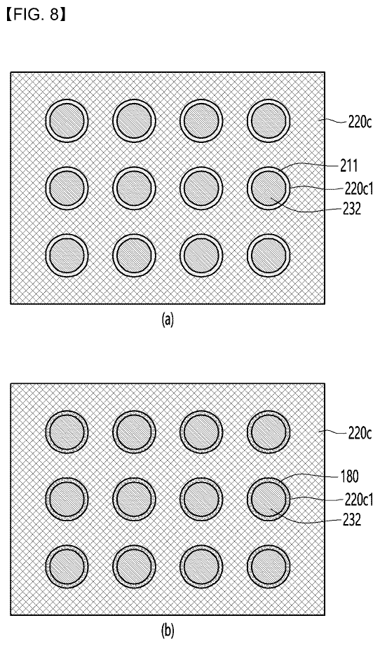

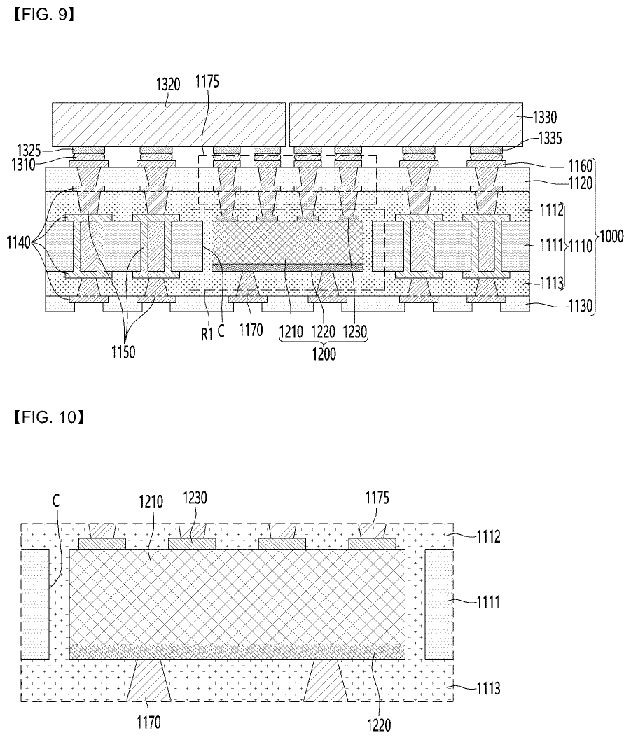

FIG. 9 is a cross-sectional view illustrating a semiconductor package according to a third embodiment, and FIG. 10 is an enlarged cross-sectional view of a region R1 of FIG. 7.

Referring to FIGS. 9 and 10, the semiconductor package includes a circuit board 1000, a connection member 1200, a bonding part 1310, and semiconductor devices 1320 and 1330.

The semiconductor device 1320 and 1330 includes terminals 1325 and 1335 and can be electrically connected to the electrode part of the circuit board 1000 via the bonding part 1310. At this time, a basic structure of the circuit board 1000, the connection member 1200, the bonding part 1310, and the semiconductor device 1320 and 1330 of the third embodiment corresponds to a structure of the first embodiment of FIG. 1, and thus, a detailed description thereof will be omitted.

The connection member 1200 includes an insulating part 1210, a metal layer 1220, and a pad part 1230.

At this time, the circuit board 1000 includes a cavity C, and the connection member 1200 is disposed in the cavity C. At this time, the cavity C may penetrate the first layer 1111 of the insulating layer 1110 of the circuit board 1000. Accordingly, the connection member 1200 may be disposed in the cavity C provided in the first layer 1111 of the insulating layer 1110. In addition, the insulating layer 1110 of the circuit board 1000 may include a second layer 1112 and a third layer 1113 that are respectively disposed above and below the first layer 1111 and fill the cavity C.

In addition, the circuit board may include a first protective layer 1120 disposed on the insulating layer 1110 and a second protective layer 1130 disposed under the insulating layer 1110.

In addition, the circuit board 1000 may include a wiring electrode 1140, a via electrode 1150, and a bump part 1160. Furthermore, the circuit board 1000 may include a first electrode part 1170 disposed under the connection member 1200 while overlapping the connection member 1200 in the vertical direction, and a second electrode part 1175 disposed on the connection member 1200 while overlapping the connection member 1200 in the vertical direction.

At this time, the basic structure of the circuit board 1000 corresponds to the structure of the first embodiment, and a detailed description thereof is omitted.

The connection member 1200 is embedded in the insulating layer 1110 of the circuit board 1000. At this time, the metal layer 1220 of the connection member 1200 may be in direct contact with the insulating layer 1110 of the circuit board 1000. For example, the metal layer 1220 of the connection member 1200 may be covered by the insulating layer 1110 of the circuit board 1000.

Specifically, the connection member of the first embodiment is bonded and/or fixed to the circuit board by an adhesive member 180 disposed on the electrode pattern of the circuit board. Accordingly, the metal layer of the connection member of the first embodiment has a structure that contacts the adhesive member. Furthermore, in the first embodiment, the via part 151 provided in the circuit board has a structure that directly contacts the electrode pattern 141.

In contrast, the circuit board 1000 of the third embodiment may use a separate adhesive film (not shown) to place the connection member 1200 on the first layer 1111 of the insulating layer 1110, and then perform a process of removing the adhesive film. Accordingly, the circuit board 1000 of the third embodiment may not include an adhesive member for fixing the connection member 1200. For example, at least a portion of the insulating layer 1110 of the circuit board 1000 may be provided to cover the metal layer 1220 of the connection member 1200.

In addition, the electrode part of the circuit board 1000 includes a first electrode part 1170 directly connected to the metal layer 1220 of the connection member 1200. For example, the first electrode part 1170 penetrates at least a portion of the insulating layer 1110 of the circuit board 1000. The first electrode part 1170 overlaps the connection member 1200 in a vertical direction and is disposed under the connection member 1200.

At this time, the first electrode part 1170 includes a via part, and an upper surface of the via part is directly connected to a lower surface of the metal layer 1220 of the connection member 1200. For example, in the third embodiment, a through hole exposing at least a portion of the metal layer 1220 of the connection member 1200 is formed while the connection member 1200 is embedded in the insulating layer 1110, and the through hole is filled with a conductive material to form the first electrode part 1170. Accordingly, the circuit board 1000 of the third embodiment may include a first electrode part 1170 including a via part directly connected to the metal layer 1220 of the connection member 1200.

Through this, the embodiment can enable the first electrode part 1170 to be directly connected to the metal layer 1220 of the connection member 1200, thereby more efficiently dissipating heat generated from the connection member 1200 and/or the semiconductor device, thereby further improving the heat dissipation characteristics of the semiconductor package.

Meanwhile, if the pad part 1230 of the connection member 1200 has an upper pad and a lower pad, the first electrode part 1170 can be divided into a plurality of groups.

For example, if the pad part 1230 has an upper pad and a lower pad, the metal layer 1220 can have a through hole, and the lower pad can be disposed within the through hole of the metal layer 1230.

Accordingly, the first electrode part 1170 may include a first group of first electrode parts overlapping the metal layer 1230 in the vertical direction, and a second group of first electrode parts overlapping the lower pad in the vertical direction. The first electrode parts of the first group may be connected to the metal layer 1230 and function as heat dissipation electrodes, and the second electrode parts of the second group may be connected to the lower pad and function to transmit communication signals or power signals.

The following describes in detail a method for manufacturing a semiconductor package according to an embodiment.

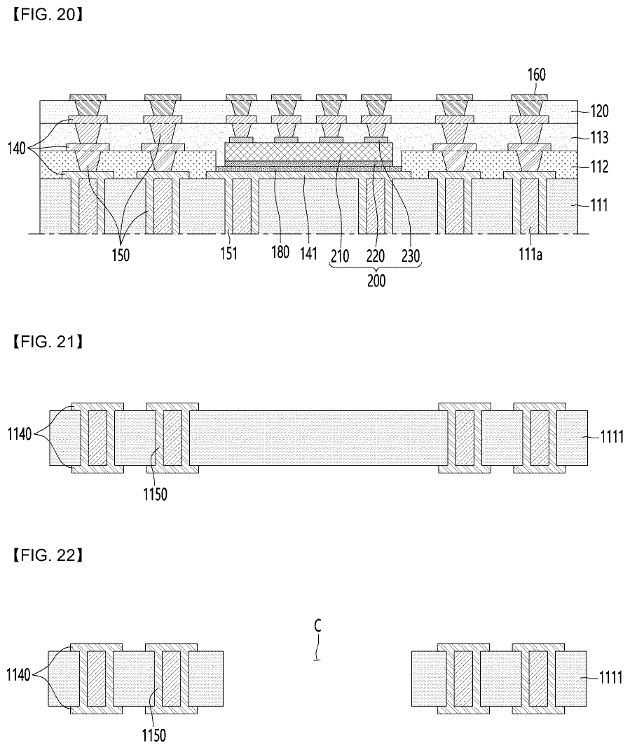

FIGS. 11 to 20 are cross-sectional views illustrating a method of manufacturing the semiconductor package shown in FIG. 1 in order of processes, and FIGS. 21 to 30 are cross-sectional views illustrating a method of manufacturing the semiconductor package shown in FIG. 9 in order of processes.

Referring to FIG. 11, the embodiment prepares the first layer 111 of the insulating layer 110. In addition, the embodiment may perform a process of forming a wiring electrode 140 and a via electrode 150 on the first layer 111 of the insulating layer 110. For example, the embodiment may perform a process of forming a wiring electrode on the upper and lower surfaces of the first layer 111 of the insulating layer 110, and a process of forming a via electrode 151 and a filling portion 111a penetrating the first layer 111. At this time, the wiring electrode 140 disposed on the first layer 111 of the insulating layer 110 may include an electrode pattern 141.

Next, the embodiment performs a process of laminating a second layer 112 on the first layer 111 of the insulating layer 110. In addition, the embodiment performs a process of forming a via electrode penetrating the second layer 112 of the insulating layer 110 and a wiring electrode on the second layer 112.

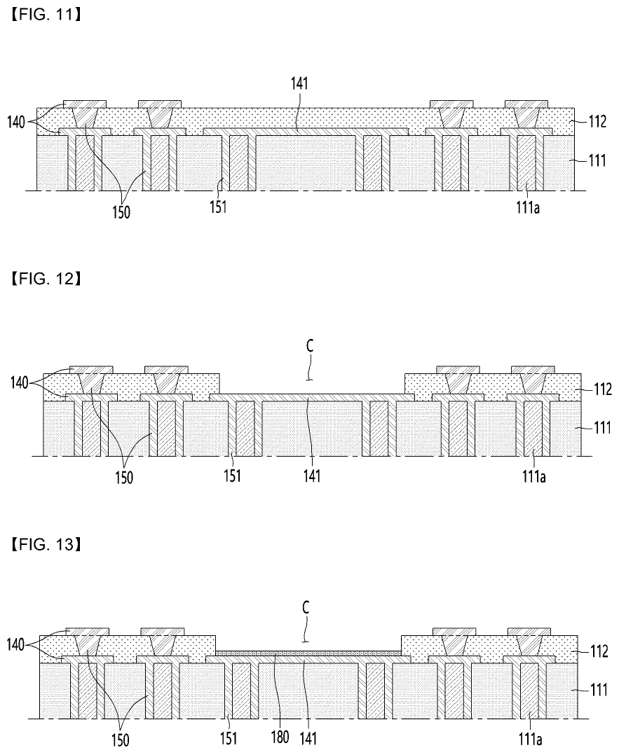

Referring to FIG. 12, the embodiment performs a process of forming a cavity C in a second layer 112 of an insulating layer 110. At this time, an electrode pattern 141 is provided on the first layer 111 of the insulating layer 110, and the cavity C overlaps the electrode pattern 141 in the vertical direction. For example, at least a portion of the upper surface of the electrode pattern 141 may be exposed through the cavity C. At this time, the cavity C may be formed through a laser process, and the electrode pattern 141 may function as a laser stopper in the laser process.

Referring to FIG. 13, the embodiment may perform a process of applying an adhesive member 180 on an electrode pattern 141. At this time, a width of the electrode pattern 141 may be larger than the width of the cavity C, and accordingly, a width of the adhesive member 180 may be smaller than a width of the electrode pattern 141.

Referring to FIG. 14, the embodiment may perform a process of attaching a connection member 200 on the adhesive member 180. At this time, the connection member 200 includes a metal layer 220. Therefore, the metal layer 220 of the connection member 200 may be attached on the adhesive member 180. Through this, the embodiment can apply uniform pressure to the connection member 200 using the metal layer 220, and further improve the adhesion between the connection member 200 and the adhesive member 180, thereby enabling the connection member 200 to be firmly and stably bonded to the adhesive member 180.

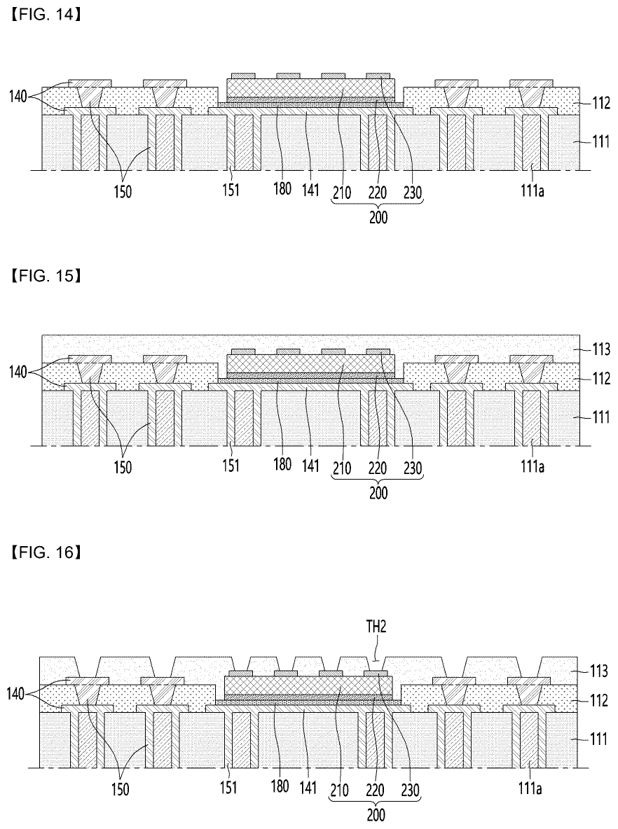

Referring to FIG. 15, the embodiment performs a process of laminating a third layer 113 of the insulating layer 110 on a second layer 112 of the insulating layer 110. At this time, the third layer 113 of the insulating layer 110 can fill the cavity C provided in the second layer 112.

Referring to FIG. 16, the embodiment performs a process of forming a through hole TH1 penetrating the third layer 113 of the insulating layer 110. For example, the embodiment performs a process of forming a through hole TH1 that overlaps the pad part 230 of the connection member 200 in the vertical direction.

Referring to FIG. 17, the embodiment performs a process of forming a via electrode and a wiring electrode by filling the through hole TH1 with a conductive material.

Referring to FIG. 18, the embodiment performs a process of laminating a first protective layer 120 on the third layer 113 of the insulating layer 110.

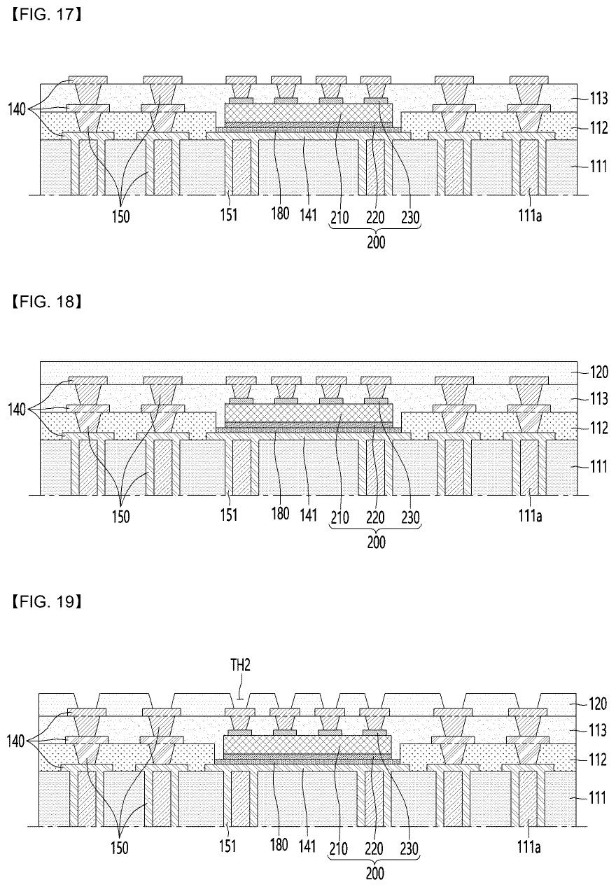

Referring to FIG. 19, the embodiment performs a process of forming a through hole TH2 penetrating the first protective layer 120.

Referring to FIG. 20, the embodiment performs a process of forming a bump part 160 by filling the through hole TH2 of the first protective layer 120 with a conductive material.

Meanwhile, the method of manufacturing the semiconductor package of FIG. 9 is described as follows.

Referring to FIG. 21, the embodiment prepares a first layer 1111 of an insulating layer 1110. Furthermore, the embodiment may perform a process of forming a wiring electrode 1140 on the upper and lower surfaces of the first layer 1111 of the insulating layer 1110, and also forming a via electrode 1150 penetrating the first layer 1111.

Referring to FIG. 22, the embodiment may perform a process of forming a cavity C in a form of a through hole penetrating the upper and lower surfaces of the first layer 1111 by processing the first layer 1111 of the insulating layer 1110.

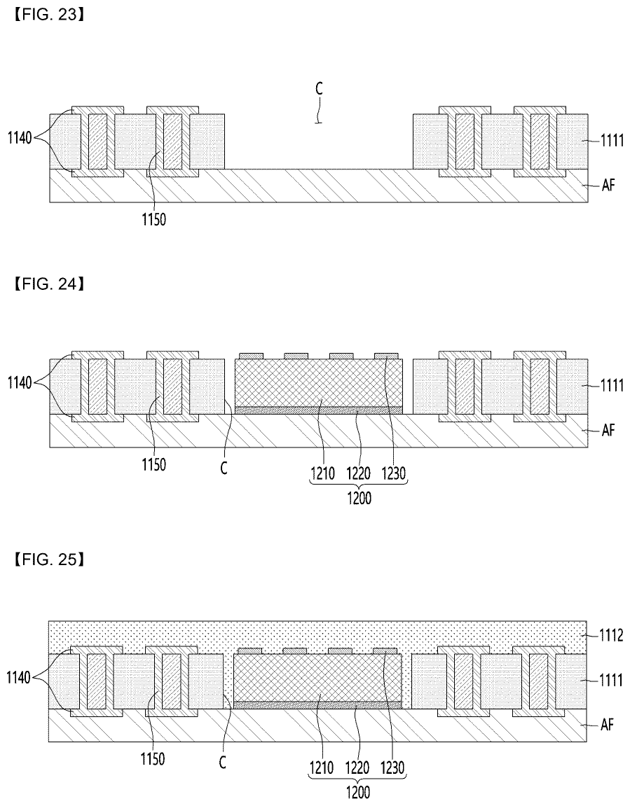

Referring to FIG. 23, the embodiment may perform a process of placing an adhesive film AF under the first layer 1111 of the insulating layer 1110. At this time, the adhesive film AF is provided to block the lower portion of the cavity C provided in the first layer 1111 of the insulating layer 1110.

Referring to FIG. 24, the embodiment performs a process of attaching a connection member 1200 within the cavity C of the first layer 1111 of the insulating layer 1110 on the adhesive film AF. At this time, the connection member 1200 may be fixed by the adhesive force of the adhesive film AF, and thus may be disposed in the cavity C of the first layer 1111 of the insulating layer 1110.

Referring to FIG. 25, the embodiment may perform a process of forming a second layer 1112 of the insulating layer 1110 that fills the cavity C on the first layer 1111 of the insulating layer 1110. Accordingly, the second layer 1112 may be formed to surround a side portion of the connection member 1200 within the cavity C.

Referring to FIG. 26, the embodiment may perform a process of removing the adhesive film AF. At this time, the connection member 1200 is fixed by the second layer 1112 of the insulating layer 1110, thereby facilitating the removal of the adhesive film AF.

Referring to FIG. 27, the embodiment may perform a process of laminating a third layer 1113 under the first layer 1111 of the insulating layer 1110.

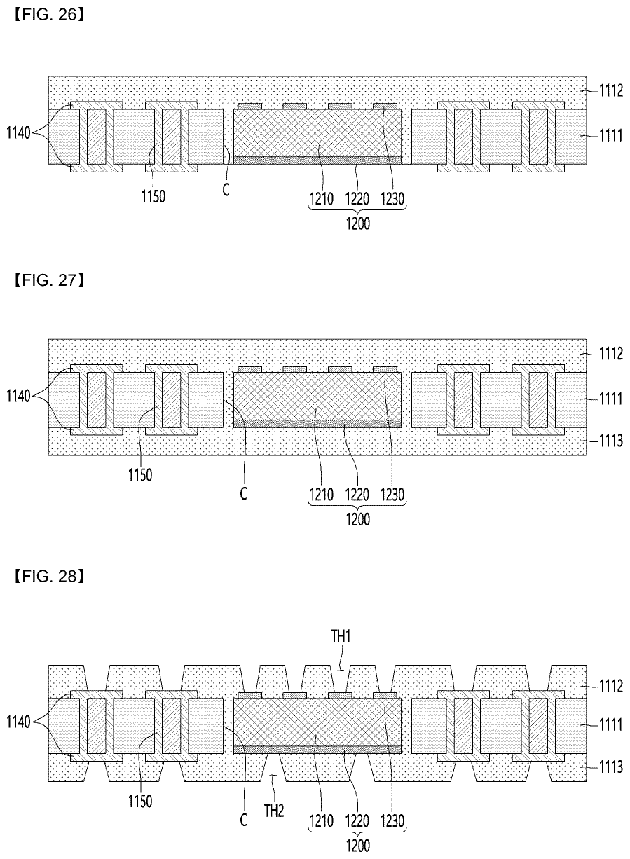

Referring to FIG. 28, the embodiment may perform a process of forming through holes TH1 and TH2 that penetrate the second layer 1112 and the third layer 1113 of the insulating layer 1110, respectively. At this time, at least a portion of the through hole TH1 penetrating the second layer 1112 of the insulating layer 1110 may overlap vertically with the pad part 1210 provided in the connection member 1200. In addition, at least a portion of the through hole TH2 penetrating the third layer 1113 of the insulating layer 1110 may overlap vertically with the metal layer 1220 provided in the connection member 1200.

Referring to FIG. 29, the embodiment may perform a process of forming via electrodes that fill the through holes TH1 and TH2 of the second layer 1112 and the third layer 1113 of the insulating layer 1110. In addition, the embodiment may perform a process of forming wiring electrodes on an upper portion of the second layer 1112 and a lower portion of the third layer 1113 of the insulating layer 1110, respectively.

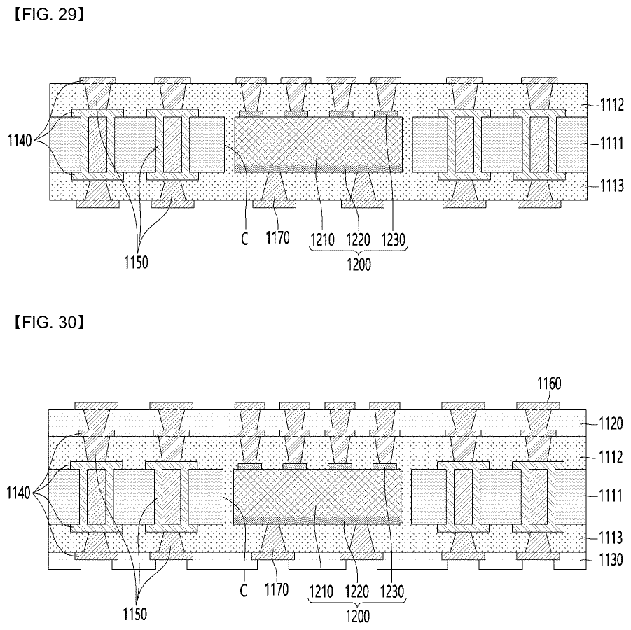

Referring to FIG. 30, the embodiment may perform a process of forming a first protective layer 1120 on a second layer 1112 of an insulating layer 1110 and forming a second protective layer 1130 under a third layer 1113. In addition, the embodiment may perform a process of forming a bump part 1160 penetrating the first protective layer 1120.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a first insulating layer having a cavity;
a connection member disposed in the cavity of the first insulating layer, and
a second insulating layer disposed on the first insulating layer and embedding the connection member,
wherein a lower surface of the connection member has a step, and
wherein the second insulating layer is in contact with at least a portion of the step of the connection member.

2. The circuit board of claim 1, wherein the connection member includes an insulating part, and
wherein a lower surface of the insulating part has a step.

3. The circuit board of claim 2, wherein the connection member further includes a metal layer disposed on the lower surface of the insulating part, and
wherein a lower surface of the metal layer has a step corresponding to the step of the insulating part.

4. The circuit board of claim 3, wherein the insulating part includes an inner insulating part and a lower insulating part disposed on a lower surface of the inner insulating part, and
wherein the metal layer is disposed on a lower surface of the lower insulating part.

5. The circuit board of claim 4, wherein the lower surface of the lower insulating part and the lower surface of the metal layer each have a step.

6. The circuit board of claim 4, wherein a width of the inner insulating part in a horizontal direction is smaller than a width of the lower insulating part in the horizontal direction, and
wherein the metal layer is provided with a step on the lower surface of the inner insulating part, a side surface of the lower insulating part, and the lower surface of the lower insulating part.

7. The circuit board of claim 3, further comprising:
an electrode part embedded in the first insulating layer,
wherein the electrode part includes an electrode pattern disposed on a bottom surface of the cavity and overlapping the connection member in a vertical direction, and
wherein a width of the electrode pattern in the horizontal direction is greater than a width of the metal layer in the horizontal direction.

8. The circuit board of claim 7, wherein the width of the metal layer in the horizontal direction is the same as a width of the insulating part of the connection member in the horizontal direction.

9. The circuit board of claim 7, further comprising:
an adhesive member disposed between the electrode pattern and the metal layer of the connection member,
wherein an upper surface of the adhesive member is in contact with the metal layer, and
wherein a lower surface of the adhesive member is in contact with the electrode pattern.

10. The circuit board of claim 9, wherein a width of the adhesive member in the horizontal direction is smaller than a width of the electrode pattern in the horizontal direction.

11. The circuit board of claim 9, wherein a width of the adhesive member in the horizontal direction is smaller than a width of the electrode pattern in the horizontal direction.

12. The circuit board of claim 11, wherein the adhesive member includes a first portion in contact with an upper surface of the electrode pattern and a lower surface of the metal layer, and a second portion extending upward from the first portion and in contact with a side surface of the metal layer.

13. The circuit board of claim 9, the adhesive member includes an overlapping region overlapping the connection member in the vertical direction, and wherein the overlapping region includes a contact portion that contacts the connection member and a non-contact portion that does not contact the connection member.

14. The circuit board of claim 9, further comprising:
a third insulating layer disposed below the first insulating layer, and
wherein the electrode part includes a via electrode penetrating at least a portion of the third insulating layer and overlapping the connection member in the vertical direction.

15. The circuit board of claim 14, wherein the via electrode is electrically connected to the electrode pattern.

16. The circuit board of claim 15, wherein the metal layer of the connection member has a plurality of through holes, and
wherein the connection member includes a lower pad provided on a lower surface of the insulating part and disposed in the plurality of through holes.

17. The circuit board of claim 16, wherein an inner wall of the through hole of the metal layer is provided to surround a side surface of the lower pad at a position spaced apart from the lower pad in the horizontal direction, and
wherein at least a portion of the adhesive member is disposed between the inner wall of the through hole of the metal layer and the side surface of the lower pad.

18. The circuit board of claim 2, wherein the insulating part of the connection member is provided with an inorganic or organic material, and
wherein the metal layer is coated, deposited, or plated on the lower surface of the insulating part.

19. A circuit board comprising:
a build-up insulating layer;
a connection member embedded in the build-up insulating layer; and
an electrode part penetrating at least a portion of the build-up insulating layer and overlapping the connecting member in a vertical direction,
wherein the connection member includes an insulating part; a plurality of upper pads disposed on an upper surface of the insulating part; and a metal layer disposed on a lower surface of the insulating part,
wherein the electrode part includes a plurality of first via electrodes disposed under the connection member and spaced apart from each other in a horizontal direction, and a plurality of second via electrodes disposed on the connection member and connected to the plurality of upper pads, and
wherein the plurality of first via electrodes are electrically connected to each other through the metal layer.

20. The circuit board of claim 19, wherein a lower surface of the metal layer has a step, and
wherein the build-up insulating layer is in contact with the step.
